(19) United States
(12) Patent Application Publication
(10) Pub. No.: US 2011/0095266 A1
(43) Pub. Date: Apr. 28, 2011

(54) PHOTODETECTOR AND METHOD FOR THE PRODUCTION THEREOF

(76) Inventors: Oliver Hayden, Herzogenaurach (DE); Sandro Francesco Tedde, Erlangen (DE)

(21) Appl. No.: 12/737,264

(22) PCT Filed: Jun. 24, 2009
(86) PCT No.: PCT/EP2009/057864

§ 371 Date: Dec. 23, 2010

(30) Foreign Application Priority Data
Jun. 25, 2008 (DE) 10 2008 029 782.8

(51) Int. Cl. H01L 31/0256

(52) U.S. Cl. 257/21; 438/57; 977/715; 977/773; 257/E31.003

(57) ABSTRACT

X-ray radiation is converted by a photodetector into an electric charge. Nanoparticles are incorporated into the active organic layer of the photodetector.

### CROSS REFERENCE TO RELATED APPLICATIONS

This application is the U.S. national stage of International Application No. PCT/EP2009/057864, filed Jun. 24, 2009 and claims the benefit thereof. The International Application claims the benefits of German Application No. 102008029782.2 filed on Jun. 25, 2008, both applications are incorporated by reference herein in their entirety.

### BACKGROUND

Described below is a photodetector for X-ray radiation, in which X-ray radiation is converted into electrical charge.

In the detection of X-ray radiation, provision is made of direct and indirect conversion of the X-ray radiation into electrical charge, wherein the indirect method has at least the disadvantage that in this case firstly the photon from the X-ray radiation interacts in a scintillator with a material that finally exhibits emission, which also produces scattered light. As a result of the scattered light, the resolution of the indirect method is poorer than in the case of the direct method.

In the case of direct conversion, a significantly higher resolution is achieved because unsharpness as a result of scattered light does not arise. High image resolution with a flat bed scanner (FPD) is achieved by direct conversion of X-ray radiation into electrical charge carriers in the photodiode or photoconductor. At present, the production of these photodiodes and photoconductors is complex and cost-intensive because the material that enables direct conversion is generally amorphous selenium, typical layer thicknesses being 200 μm. Other materials for direct conversion can be: CdTe (cadmium telluride) or CdZnTe (cadmium zinc telluride).

Y. Wang et al. (Science 1996, 273, 632-634) report on a photoconductor wherein nanoparticles composed of inorganic materials such as bismuth triiodide (BiI3), for example, are embedded with a high proportion by weight in an organic matrix (nylon-11). This technique makes use of mechanically comminuted X-ray absorbers with not very defined size and surface structure, which are designated as nanoparticles. This embedding of the mechanically comminuted particles into a polymeric matrix proves to be difficult. Furthermore, small conductive polymers (polysilane, polycarbazole) are utilized as a polymeric matrix. The current transport in these hybrid photoconductors is substantially achieved by the charge transport via the not very defined grain boundaries of iodine salts and is therefore relatively slow and poor.

The use of organic photodiodes, such as are known from WO 2007/017470, for example, is known only in connection with indirect conversion. Otherwise, only inorganic photodetectors have been utilized hitherto in the art for the conversion of X-ray radiation by photodetectors.

Compared with inorganic photodetectors, however, organic photodetectors have the crucial advantage that they can be produced in a large-area fashion.

### SUMMARY

The problem addressed by the photodector described below, therefore, is that of overcoming the disadvantages of the known art and enabling direct conversion by organic photodetectors.

An organic photodetector for the direct conversion of X-ray radiation, includes on a substrate, an electrode, at least one active organic layer and thereon a top electrode, wherein semiconducting nanoparticles are incorporated in the active layer in a semiconducting organic matrix, the nanoparticles enabling the direct conversion of X-ray radiation into electrical charges. Moreover, the subject matter is a method for the production of a photodetector, wherein at least the organic active layer is produced from solution (“wet-chemically”).

The organic photodetector is distinguished by the fact that the conversion of the X-ray radiation takes place in the same layer as the generation of the charges. This ensures that a high resolution can be achieved for X-ray recordings. Heretofore this has only been able to be realized using complex inorganic photodetectors.

Very generally it is possible to use different semiconducting nanoparticles or mixtures of different nanoparticles, for example also in the form of crystals.

According to one embodiment, semiconducting nanocrystals are incorporated into the semiconducting layer, the nanocrystals in turn may be produced by chemical synthesis.

During the commination for producing the nanoparticles, defects occur which influence the surface properties of the nanoparticles.

Typical nanoparticles are compound semiconductors of group II-VI or group III-V. Semiconductors of group IV can also be used. Ideal nanoparticles exhibit high X-ray absorption properties, such as lead sulfide (PbS), lead selenide (PbSe), mercury sulfide (HgS), mercury selenide (HgSe), mercury telluride (HgTe). Semiconducting nanoparticles or nanocrystals in which quantization of the energy levels occurs (quantum dots) include diameters of 1 to typically 20 nm, particularly 1 to 15 nm, and more particularly 1 to 10 nm. In the case where the semiconducting nanocrystals have a larger diameter, they have bulk properties which can likewise be utilized for direct conversion. The starting substance of the organic active layer of the photodetector is present in a dissolved fashion or as a suspension in a solvent and is applied to a lower layer such as, for example, a charge-coupled device (CCD) or a thin-film transistor (TFT) panel by wet-chemical process steps (spin-coating, blade coating, printing, doctor blading, spray coating, rolling, etc.). The layer thicknesses are in the nanometers or micrometers range, depending on the production method. Only a top electrode without structuring is necessary.

The embedding of the quantum dots into the semiconducting organic, in particular polymeric, matrix can also be effected, inter alia, by a multiple spray coating method. A method of this type is described, for example, in DE 10 2008 015 290, not yet published, as a multiple spray coating system for the production of polymer-based electronic components.

According to a particularly advantageous embodiment, in order to ensure efficient X-ray absorption, thick layers having thicknesses of >100 μm are produced for direct conversion. These layers can be produced, by the wet-chemical methods mentioned above, all at once or by multilayered layers having a regular sequence of a semiconductor layer and an intermediate layer for the construction of the overall layer. In this case, the semiconductor layer is respectively applied wet-chemically, for example by spin-coating, blade coating, printing, doctor blading, rolling, etc. The intermediate layer may have good electron and hole transport capability and prevents partial dissolution of underlying organic semiconductor layers during the application of the upper layers. The schematic construction of such a multilayer construction is illustrated in FIG. 3.

However, large layer thicknesses of hundreds of micrometers can also be produced by spray coating or an immersion process.

Multilayered layers can also be achieved, for example, by stacked photodiodes or photoconductors, as shown in FIG. 4.

The process may be effected at temperatures of up to at most 200° C., such that it is also possible to work on flexible substrates.

According to one embodiment, the proportion by volume of nanoparticles, such as PbS, for example, in the absorber layer is very high (typically >50%, particularly >55% or more particularly >60%) in order to ensure corresponding high absorption of the X-ray radiation. In order to mask out ambient light, e.g. a metal layer is applied to the diodes, such as above the encapsulation.

### BRIEF DESCRIPTION OF THE DRAWINGS

These and other aspects and advantages will become more apparent and more readily appreciated from the following description of the exemplary embodiments, taken in conjunction with the accompanying drawings of which:

FIG. 1 is a perspective view of the typical construction of an organic photodiode,

FIG. 2 is a schematic cross section of a pixelated photodetector with nanoparticles embedded in the active organic layer,

FIG. 3 is a schematic cross section of a multilayer construction for obtaining thicker layers, and

FIG. 4 is a schematic cross section of the construction of a stacked diode.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

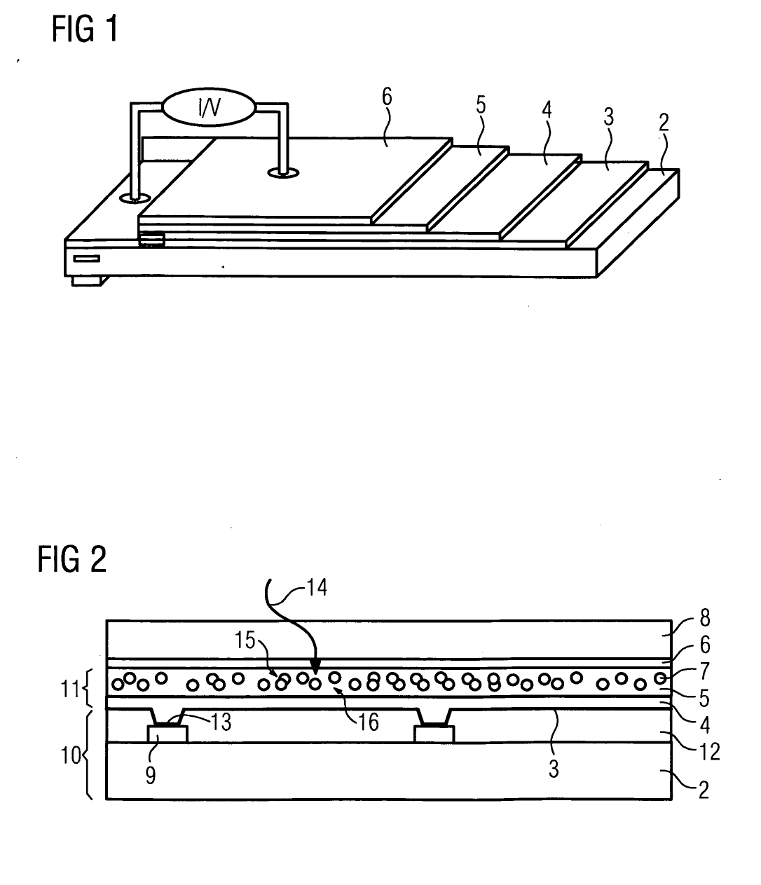

FIG. 1 shows an organic photodiode 1 on a substrate 2 with a bottom, that may be transparent, electrode 3, thereon optionally a hole conducting layer 4, possibly a PEDOT/PSS layer, and thereabove an organic photoconductive layer 5 in the form of a bulk heterojunction with thereabove a top electrode 6. By way of example, the organically based photodiodes have a vertical layer system, wherein a PEDOT layer including a P3HT-PCBM blend is situated between a bottom indium tin oxide electrode (ITO electrode) and a top electrode, including calcium and silver, for example. The blend of the two components P3HT (poly(hexylthiophene)-2,5-diyl) as absorber and/or hole transport component and PCBM phenyl-C61-butyric acid methyl ester as electron acceptor and/or electron donor acts as a so-called “bulk heterojunction”, that is to say that the charge carriers are separated at the interfaces of the two materials which form within the entire layer volume. The solution can be modified by substitution or admixing of further materials.

The organic photodiode 1 is operated in the reverse direction and has a low dark current.

Nanoparticles (not discernable here) are added to the active organic semiconducting layer. According to one embodiment, nanocrystals are used as nanoparticles.

The suitability of the layer modified with nanoparticles for the conversion of the X-ray radiation is achieved by the energy gap in semiconductor crystals, which can also be present in a quantized manner as in the case of very small nanocrystals. If photons or high-energy X-ray quanta having an energy greater than the energy gap of the semiconductor crystal are absorbed, excitons (electron-hole pairs) are generated. If the size of the nanocrystal is reduced in all three dimensions, the number of energy levels is reduced and the size of the energy gap between the quantized valence band and conduction band becomes dependent on the diameter of the crystal and as a result the absorption or emission behavior thereof also changes. Thus, by way of example, it is possible to raise the energy gap of PbS from approximately 0.42 eV (corresponding to a light wavelength of approximately 3 μm) in nanocrystals having a size of approximately 10 nm to 1 eV (corresponding to a light wavelength of 1240 nm).

X-ray radiation absorbed by nanoparticles or nanocrystals generates excitons. The resultant electron-hole pairs in the organic semiconductor are separated in the electric field or at the interfaces of organic semiconductor and nanocrystals and can flow away through percolation paths to the corresponding electrodes as a “photocurrent”.

FIG. 2 shows a schematic construction of a pixelated flat-panel photodetector having nanoparticles 7 embedded in the organic active layer 5. The conversion of the X-ray beam takes place directly in the organic photodiode.

The above-described bulk heterojunction composed of electron acceptor or electron donor with embedded semiconducting nanoparticles or nanocrystals acts as absorber.

Besides the construction—illustrated in FIG. 1—of the photodiode on glass substrate 2, which has a structured passivation layer 12 with through-contacts 9 to the drain electrode 13 of the bottom electrode layer 3, the nanoparticles 7 in the organic active layer 5 are also clearly discernable here (in total frontplane). The glass substrate includes, for example, an inorganic transistor array including a-Si-TFT, that is to say amorphous silicon thin-film transistors (backplane), which are commercially available. The passivation layers 12 and 8 serve either to encapsulate the photodiodes (e.g. glass encapsulation) or to prevent the conductivity between individual a-Si-TFT pixels.

Situated on the bottom electrode layer 3 is the optional hole transporter layer 4, on which is situated in turn the organic active layer 5, which, by way of example, has a thickness in the range of from 100 to 1500 μm, such as approximately 500 μm. On this layer there is the upper construction analogously to that known from FIG. 1.

An X-ray beam 14 that impinges on a nanoparticle 7 is absorbed there and an exciton (not shown) is released therefrom. A charge carrier pair arises, i.e., an electron 15 and a hole 16 as shown.

FIG. 2 additionally shows that the substrate 2 and the lower passivation layer 12 together with the bottom structured electrode 3 form the commercially available backplane 10, whereas the upper part of the device with the active organic layer 5 constitutes the frontplane 11.

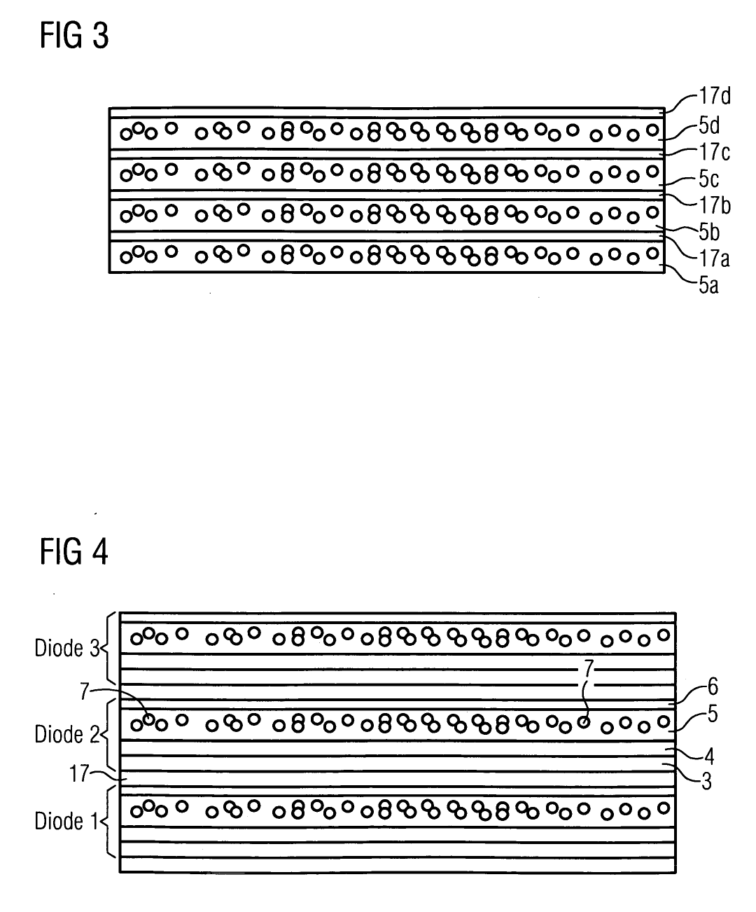

FIG. 3 shows a multilayer construction which enables the construction of thicker layers using known wet-chemical methods. In this case, the individual organic active layers 5, that is to say 5a to 5d, applied using “normal” thin-film technology, filled in each case with nanoparticles 7, are discernable and so additionally is the so-called “magic layer”, the intermediate layers 17, that is to say 17a to 17d, separating the individual thin layers from one another. The intermediate layer 17, as already described above, may have a good electron and/or hole conductivity and protects the lower layer in each case against partial dissolution during the application of the next layer.

Finally, FIG. 4 shows a schematic construction of a stacked diode 1. Layers having any desired thickness can be produced with n stacked diodes. The bottom electrode 3, the optional hole transport layer 4, the organic active layer 5 with the nanoparticles 7, the cathode 6 and the upper intermediate layer 17 are discernable in each case only schematically.

The following are advantages over the known art:
a) Organic photodiode or organic photoconductor having a low dark current and an embedded X-ray absorber (nanoparticles or nanocrystals).
b) Nanoparticles or nanocrystals having defined diameters (produced from solution) lead to reproducible absorbers having smaller charge carrier traps in comparison with mechanically comminuted and therefore not very defined nanoparticles.
c) By virtue of the wet-chemical processing it is possible to carry out diode fabrications on TFT panels for direct conversion of X-ray radiation without the use of vacuum technology and traditional semiconductor process technology.
d) Embedding of the nanocrystalline X-ray absorber into a semiconducting polymer permits large-area processing.
e) The fabrication of the organic diodes can be effected on flexible TFT substrates on account of the low (<200° C.) processing temperatures.
f) Layers of hundreds of μm with sufficient X-ray absorption can be achieved by spray coating or by multilayers.

Cost-effective production of a direct X-ray converter based on a composite of organic semiconductor and semiconducting nanoparticles can be applied in a large-area fashion as an organic photodiode or photoconductor on flatbed scanners by wet-chemical processes.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-14. (canceled)

15. An organic photodetector on a substrate for direct conversion of X-ray radiation, comprising
a low electrode on the substrate;
at least one active organic layer, incorporating semiconducting nanoparticles in a semiconducting organic matrix, the semiconducting nanoparticles enabling the direct conversion of X-ray radiation into electrical charges; and
a top electrode.

16. The photodetector as claimed in claim 15, wherein the nanoparticles are nanocrystals.

17. The photodetector as claimed in claim 16, wherein the nanocrystals are produced by chemical synthesis.

18. The photodetector as claimed in claim 17, wherein the nanocrystals are compound semiconductors of group II-VI, group IV or group III-V.

19. The photodetector as claimed in claim 18, wherein the nanocrystals are composed of lead sulfide, lead selenide, mercury sulfide, mercury selenide (HgSe) and/or mercury telluride.

20. The photodetector as claimed in claim 19, wherein the nanocrystals have typical diameters of 1 to 20 nm.

21. The photodetector as claimed in claim 20, wherein the at least one active organic layer has a layer thickness of over 100 μm.

22. The photodetector as claimed in claim 21, wherein the layer thickness is achieved by multilayeredness of the at least one active organic layer with an intermediate layer.

23. The photodetector as claimed in claim 21, wherein the layer thickness arises as a result of a stacking of the photodiodes.

24. The photodetector as claimed in claim 23, further comprising a metal layer.

25. The photodetector as claimed in claim 24, wherein the nanoparticles are incorporated in the at least one active organic layer in a proportion by volume of at least 50%.

26. A method for the production of a photodetector, comprising:
producing at least an organic active layer from a solution.

27. The method as claimed in claim 26, wherein said producing of at least the organic active layer is by spin-coating, blade coating, printing, doctor blading, spray coating and/or rolling.

28. The method as claimed in claim 27, wherein said producing is at a temperature of at most 200° C.
